(19) United States
(12) Patent Application Publication
(10) Pub. No.: US 2010/0236630 A1
(43) Pub. Date: Sep. 23, 2010

(54) CHEMICAL VAPOR DEPOSITION OF CuInxGa1-x(SeyS1-y)2 THIN FILMS AND USES THEREOF

(75) Inventors: W.K. KIM, Gyeongsan-si (KR); Tim Anderson, Gainesville, FL (US)

Correspondence Address: SALIWANCHIK LLOYD & SALIWANCHIK;A PROFESSIONAL ASSOCIATION, PO Box 142950, GAINESVILLE, FL, 32614, US

(73) Assignee: UNIVERSITY OF FLORIDA RESEARCH FOUNDATION INC., GAINESVILLE, FL (US)

(21) Appl. No.: 12/602,203

(22) PCT Filed: May 30, 2008
(86) PCT No.: PCT/US08/65400

§ 371 Date: Jun. 7, 2010

Related U.S. Application Data
(60) Provisional application No. 60/940,900, filed on May 30, 2007.

(51) Int. Cl. H01L 31/0272; B32B 9/04; B32B 27/06; B32B 17/06; B32B 15/04; H01L 21/36

(52) U.S. Cl. 136/262; 428/446; 428/697; 428/432; 428/457; 438/95; 257/E21.461

(57) ABSTRACT

The subject application relates to a chemical vapor (CV) deposition technique to form CuInₓGa₁₋ₓ(Se_{y}S_{1-y})₂, compounds. As a copper source, solid copper can be used with a HCl transport gas and Cu₃Cl₃ is expected to be a major Cu-containing vapor species in this system, Liquid indium and HCl transport gas are appropriate for the indium source to provide InCl vapor species. Since selenium and sulphur are relatively highly volatile, their vapor can be carried by an inert gas without an additional transport gas, although H₂Se and H₂S can be used. Each source temperature can be controlled separately so as to provide a sufficient and stable vapor flux. Also provided by the subject application are CV-deposited substrates and devices, such as electronic devices or solar cells, that contain CV-deposited CuInₓGa₁₋ₓ(Se_{y}S_{1-y})₂ substrates.

### CROSS-REFERENCE TO RELATED APPLICATION

This application claims the benefit of U.S. Provisional Application Ser. No. 60/940,900, filed May 30, 2007, the disclosure of which is hereby incorporated by reference in its entirety, including all figures, tables and amino acid or nucleic acid sequences.

### BACKGROUND OF THE INVENTION

1. Introduction

The solid solution CuInₓGa₁₋ₓ(Se_{y}S_{1-y})₂ has been shown to be an effective absorber material for solar cells. Its use was first developed for the material with x=1 and y=1, CuInSe₂ (CIS). Subsequent demonstrations have added Ga to the group III sublattice in amounts equivalent to a range in the value of x of 1 to ˜0.7 and for x=0 (i.e., CuGaSe₂ (CGS)). There has also been demonstrations for substituting S for Se, i.e., changing the value y. The commonly used approaches for Cu(In,Ga)(Se,S)₂ thin film formation are co-deposition of elements and selenization/sulphurization of metallic precursors in H₂Se/H₂S or Se and S vapor. Recently, electrodeposition, screen printing, and spray deposition have attracted attention as the low temperature and non-vacuum process. Several processes are now being commercialized but none by chemical vapor deposition (CVD).

Fisher et al. [Fis01] have used a novel halogen supported chemical vapor phase technique in an open tube system to deposit polycrystalline thin film CuGaSe₂ (CGS). Cu₂Se and Ga₂Se₃ binary powders were successfully employed as source materials with I₂/H₂ and HCl/H₂ transport agents, respectively. CGS film deposition on soda-lime glass (SLG) substrates was carried out in a modified commercial CVD apparatus for III-V epitaxy (Aixtron VPE system) at a source and substrate temperature of T_{source}=600° C. and T_{substrate}=500° C., respectively.

Kunjachan et al. [Kun05] have performed a thermodynamic feasibility study for chemical vapor deposition of some ternary crystals including CuInSe₂ (CIS) and CuGaSe₂ (CGS) using iodine (I₂) and hydrogen iodide (HI) as transporting agents. Their calculation results showed that CIS can be grown by using I₂ but not HI as a transporting agent while CGS can be grown by either I₂ or HI.

### BRIEF SUMMARY OF THE INVENTION

The subject application relates to a chemical vapor deposition (CVD) technique to form CuInₓGa₁₋ₓ(Se_{y}S_{1-y})₂ compounds. As a copper source, copper can be transported in the vapor phase by reacting solid copper with a halide transport agent such as HCl, HBr, or HI to produce volatile copper halides. It is expected that the reaction of solid Cu with HCl forms Cu₃Cl₃ as a a major Cu-containing vapor species in this system. Liquid indium and HCl transport gas are appropriate for the indium source to provide InCl vapor species, as can liquid gallium and HCl to transport Ga as GaCl or GaCl₃, depending on the temperature. These group III metal chlorides are also available commercially and can also be used as sources. Since selenium and sulphur are relatively highly volatile, their vapor can be carried by He or other suitable carrier gas without an additional transport gas, although H₂Se and H₂S can also serve as sources. Each source temperature and gas flow can be controlled separately so as to provide a sufficient and stable vapor flux. Also provided by the subject application are CV-deposited substrates and devices, such as electronic devices or solar cells, that contain CV-deposited CuInₓGa₁₋ₓ(Se_{y}S_{1-y})₂ substrates.

### BRIEF DESCRIPTION OF THE FIGURES

FIG. 1 Equilibrium calculation of Run #1. The lines for P(Cl1Cu1), P(Cl4Cu4), P(Cl5Cu5), P(Cl2Cu1) and P(Cu1H1) are not discernable and are found along the X axis (T(K)).

FIG. 2 Equilibrium calculation of Run #2. The lines for P(Cl1Cu1), P(Cl4Cu4), P(Cl5Cu5), P(Cl2Cu1) and P(Cu1H1) are not discernable and are found along the X axis (T(K)).

FIG. 3 Equilibrium calculation of Run #3. The lines for P(Cl4Cu4), P(Cl5Cu5), P(Cl2Cu1), P(Cu1H1), P(Cu) and P(Cu2) are not discernable and are found along the X axis (T(K)).

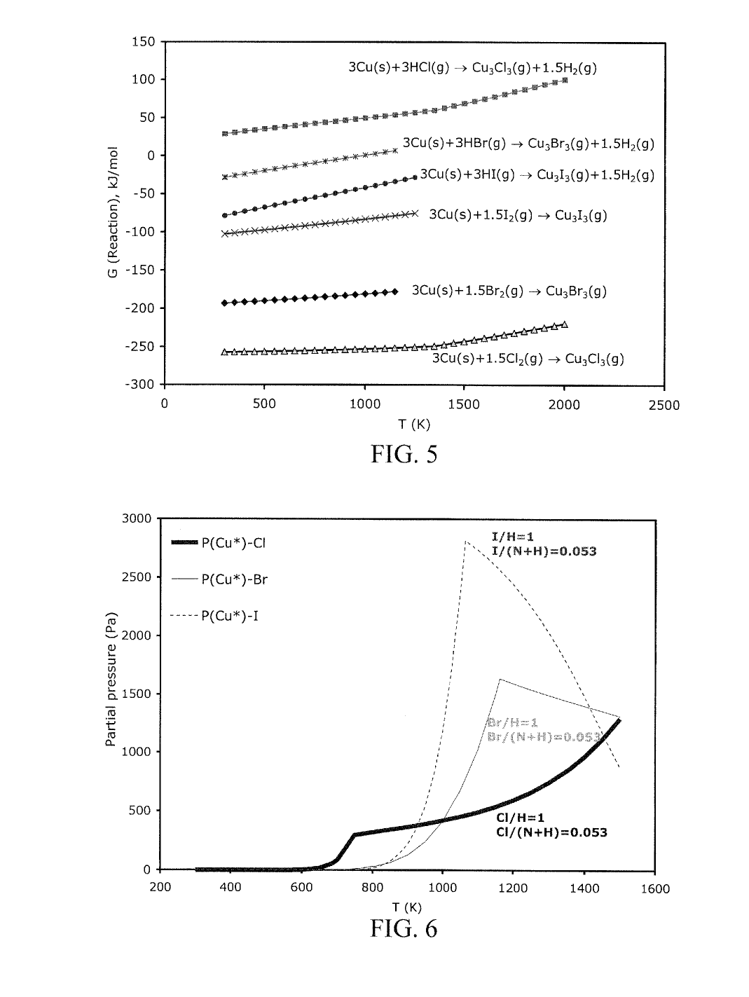

FIG. 4. Equilibrium calculation of Run #1-#4.

FIG. 5. Gibbs energy of reaction for trimer Cu-halides formation.

FIG. 6. Total vapor pressure of Cu-containing species with different hydrogen halides (HCl, HBr and HI).

FIGS. 7A-B. Equilibrium calculation of Run #(In-1). FIG. 7(A) mole fraction of each phase and FIG. 7(B) mole fraction of each species in gas phase.

FIGS. 8A-B. Equilibrium calculation of run #(In-2): [Cl]/[H]=1 & [Cl]/([He]+[H])=0.143. FIG. 8A mole fraction of each phase and FIG. 8B mole fraction of each species in gas phase.

FIGS. 9A-B. Equilibrium calculation of Run #(In-3): [Cl]/[H]=1 & [Cl]/([He]+[H])=0.053. FIG. 9A mole fraction of each phase and FIG. 9B mole fraction of each species in gas phase.

FIGS. 10A-B. Equilibrium calculation of run #(In-4): [Cl]/[H]=0.5 & [Cl]/([He]+[H])=0.053. FIG. 10A mole fraction of each phase and FIG. 10B mole fraction of each species in gas phase.

FIG. 11. Partial pressure of InCl(g) for run #(In-2) through (In-4).

FIGS. 12A-B. Equilibrium calculation of selenium source: FIG. 12A run # (Se-1): [He]/[Se]=20/80 and FIG. 12B run # (Se-2): [He]/[Se]=1/99.

FIG. 13. Composition of gas phase for run #(In-1). The lines for (Se), (Se3), (Se7), (Se4) and (Se8) are not discernable and are found along the X axis (T(K)).

FIG. 14. Schematic diagram of CuInSe₂ CVD reactor.

FIG. 15. Thermochemical equilibrium calculation for stoichiometric composition of Cu—In—Se (Run#: CIS-1).

FIG. 16. Thermochemical equilibrium calculation for Cu-rich composition of Cu—In—Se (Run#: CIS-2). FIG. 17. Thermochemical equilibrium calculation for In-rich composition of Cu—In—Se (Run#: CIS-3).

FIG. 18. Thermochemical equilibrium calculation for Se-rich composition of Cu—In—Se (Run#: CIS-4).

FIG. 19. Gas phase composition predicted by thermochemical equilibrium calculation for Se-rich composition of Cu—In—Se (Run#: CIS-4).

FIG. 20. Thermochemical equilibrium calculation for stoichiometric composition of Cu—In—Se with HCl carrier gas (Run#: CIS-5).

FIG. 21. Gas phase composition predicted by thermochemical equilibrium calculation for stoichiometric composition of Cu—In—Se with HCl carrier gas (Run#: CIS-5).

FIG. 22. Thermochemical equilibrium calculation for Cu-rich composition of Cu—In—Se with HCl carrier gas (Run#: CIS-6).

FIG. 23. Gas phase composition predicted by thermochemical equilibrium calculation for Cu-rich composition of Cu—In—Se with HCl carrier gas (Run#: CIS-6).

FIG. 24. A schematic of continuous CVD process for CuInSe₂ formation to simulate NREL 3-stage PVD process.

### DETAILED DISCLOSURE OF THE INVENTION

The subjection invention provides the following non-limiting embodiments:

1. A method for forming a CuInₓGa₁₋ₓ(Se_{y}S_{1-y})₂ film, comprising:
a. introducing a Group VI (e.g., selenium and/or sulphur) source to a reactor;
b. introducing a Group III (indium and/or Ga) source to the reactor;
c. introducing a copper source to the reactor;
d. introducing the Group VI source, the Group III source, and the copper source in the reactor in the presence of a carrier gas; and

forming a CuInₓGa₁₋ₓ(Se_{y}S_{1-y})₂ film on a substrate in the reactor. In various aspects of this embodiment, a single reactor or multiple reactors can be used for the deposition of the film and both x and y can be equal to 0 to 1 (including any fractional value between these values as understood by those skilled in the art). Additionally, the copper source(s), Group III source(s) and Group VI source(s) used in this embodiment can be pure elements (e.g., Cu, Se, S, In or Ga as sold by various vendors) or other sources of these elements (e.g., trimethyl indium or other organo-indium compounds, indium trichloride, indium monochloride or combinations thereof; pure sulphur or other organo-sulphur compounds; pure copper or other organo-copper compounds; trimethyl gallium or other organo-gallium compounds, gallium trichloride or combinations thereof). Additionally, substrates can move continuously or incrementally through the reactor or reactors. Optionally, a substrate can be stationary within the reactor or reactors.

2. The method of embodiment 1, wherein said substrate is moved continuously through the reactor.

3. The method of embodiments 1 or 2, wherein said substrate is a moving substrate that moves through the reactor.

4. The method of embodiments 1, 2 or 3, wherein said substrate is a roll-to-roll substrate. 5. The method of embodiments 1, 2, 3 or 4, wherein said substrate is a silicon wafer, plastic, resin, glass (e.g., soda-lime glass or silicon-oxide based glass), ceramic, or metal object or film, GaAs layer or any semiconductor layer or device.

6. The method of embodiments 1, 2, 3, 4 or 5, wherein said substrate is a silicon wafer or is a silicon oxide-based glass.

7. The method of embodiments 1, 2, 3, 4, 5 or 6, wherein the selenium source is pure selenium or contains selenium (e.g., organoselenium compounds).

8. The method of embodiments 1, 2, 3, 4, 5, 6 or 7, wherein the indium source is pure In or contains In (e.g., organo-indium compounds).

9. The method of embodiments 1, 2, 3, 4, 5, 6, 7 or 8, wherein the gallium source is pure Ga or contains gallium (e.g., organo-gallium compounds).

10. The method of embodiments 1, 2, 3, 4, 5, 6, 7, 8 or 9, wherein the copper source is pure copper or contains copper (e.g., organo-copper compounds).

11. The method of embodiments 1, 2, 3, 4, 5, 6, 7, 8, 9 or 10, wherein the copper source is pure copper, the gallium source is pure gallium and the indium source is pure indium.

12. The method of embodiments 1, 2, 3, 4, 5, 6, 7, 8, 9, 10 or 11, wherein the selenium, sulphur, indium, gallium, and copper sources are independently introduced into the reactor singly or in any combination within a carrier gas.

13. The method of embodiment 12, wherein the carrier gas with the Group VI sources is helium or other suitable carrier gas (e.g., nitrogen, argon, hydrogen).

14. The method of embodiment 12, wherein the carrier gas with the Group III source comprises helium or other suitable carrier gas (e.g., nitrogen, argon, hydrogen) and HCl.

15. The method of embodiment 12, wherein the carrier gas with the copper source comprises helium or other suitable carrier gas (e.g., nitrogen, argon, hydrogen) and HCl.

16. The method of embodiment 12, wherein the carrier gas with the copper source comprises nitrogen and HCl.

17. The method of embodiment 1, 2, 3, 4, 5, 6, 7, 8, 9, 10, 11, 12, 13, 14, 15 or 16, further comprising recovering unreacted materials in a recycling unit.

18. The method of embodiment 17, further comprising separating the unreacted materials.

19. The method of embodiment 1, 2, 3, 4, 5, 6, 7, 8, 9, 10, 11, 12, 13, 14, 15, 16, 17 or 18, wherein the temperature of the reactor is in the range of about 300K to about 1500K.

20. The method of embodiment 19, wherein the temperature of the reactor is in the range of about 573K to about 973K.

21. The method of embodiment 1, 2, 3, 4, 5, 6, 7, 8, 9, 10, 11, 12, 13, 14, 15, 16, 17, 18, 19 or 20, wherein the pressure of the reactor is in the range of about 1×10⁰ to 1×10⁵ Pa.

22. A CuInₓGa₁₋ₓ(Se_{y}S_{1-y})₂ coated substrate produced according to the method of any one of embodiments 1-21.

23. The CuInₓGa₁₋ₓ(Se_{y}S_{1-y})₂ coated substrate of embodiment 22, wherein said substrate is a silicon wafer, plastic, resin, glass, ceramic, or metal object or film, GaAs layer or any semiconductor layer or device.

24. A device or solar cell comprising a chemical vapor deposited CuInₓGa₁₋ₓ(Se_{y}S_{1-y})₂ on a substrate produced according to the method of any one of embodiments 1-21.

25. The device of embodiment 23, wherein said device is an electronic device.

26. The device of embodiment 23, wherein said device is a photovoltaic device.

27. The method according to any previous embodiment, further comprising the deposition of additional materials to complete a device structure/substrate or any intermediate structure thereof, wherein the additional layer(s) add to the device structure/substrate (e.g., a buffer layer, for example ZnₓCd₁₋ₓS) or a transparent conductor (e.g., doped ZnO, In-doped SnO₂)).

28. The method of any one of embodiments 1-21 or 27, wherein said group III source and group VI source are reacted with HCl, HI, HBr or combinations thereof within a carrier gas.

Thus, one aspect of the application provides a CuInₓGa₁₋ₓ(Se₃S_{1-y})₂ coated substrate produced according to the methods disclosed herein. Non-limiting examples of suitable substrates include soda-lime glass, Mo-coated soda-lime glass, stainless steel foil, polyimide sheet, silicon wafers; plastics, resins, glasses, ceramics, metal objects or films, GaAs layers or any semiconductor layer or device. Yet another aspect of the invention provides a CuInₓGa₁₋ₓ(Se_{y}S_{1-y})₂ thin film produced according to the methods described herein.

Other aspects of the invention provide a device or solar cell comprising a chemical vapor deposited CuInₓGa₁₋ₓ(Se_{y}S_{1-y})₂ substrate produced according to the methods disclosed in the subject application. In some embodiments, the device is an electronic device. Other embodiments of the invention provide a photovoltaic device containing a chemical vapor deposited CuInₓGa₁₋ₓ(Se_{y}S_{1-y})₂ substrate as described herein.

All patents, patent applications, provisional applications, and publications referred to or cited herein are incorporated by reference in their entirety, including all figures and tables, to the extent they are not inconsistent with the explicit teachings of this specification.

Following are examples which illustrate procedures for practicing the invention. The examples are illustrated for CV-deposition of CuInSe₂ noting that Ga and In behave similarly as do Se and S. These examples should not be construed as limiting. All percentages are by weight and all solvent mixture proportions are by volume unless otherwise noted.

### Materials and Methods

### 2. Equilibrium Calculation of Source Material

### 2.1 Copper Source

Thermodynamic equilibrium calculation for Cu source with an HCl carrier gas and inert gases (He and N₂) was performed using ThermoCalc software. Most data for well-identified species in the Cu—H—Cl—N—He system are obtained from the self-consistent Thermo-Calc SUB94 database. The input parameters and Cu-containing vapor species considered in this equilibrium calculation are summarized in Table 1 and 2, respectively.

TABLE 1
Input parameters for the equilibrium calculation of Cu source.

| | N | x | | | | | | Cl/ |
|---|---|---|---|---|---|---|---|---|
| Run# | (mol) | (He) | x (N) | x (H) | x (Cl) | x (Cu) | Cl/H | (Inert + H) |
| 1 | 1 | 0.15 | 0 | 0.025 | 0.025 | 0.80 | 1.0 | 0.143 |
| 2 | 1 | 0.18 | 0 | 0.01 | 0.01 | 0.80 | 1.0 | 0.053 |
| 3 | 1 | 0.17 | 0 | 0.02 | 0.01 | 0.80 | 0.5 | 0.053 |
| 4 | 1 | 0 | 0.18 | 0.01 | 0.01 | 0.80 | 1.0 | 0.053 |

Pressure: 1 × 10⁵ Pa, Temperature: 300~1500 K
He or N₂: Inert gas
HCl: Transport gas

TABLE 2
Vapor species containing Cu considered in equilibrium calculation
with a carrier gas of HCl.

Cu, Cu₂
Cu₁H₁
Cu₁Cl₂, Cu₁Cl₁, Cu₂Cl₂, Cu₃Cl₃, Cu₄Cl₄, Cu₅Cl₅

### 2.1.1 Main Cuprous Chloride Vapor Species: Cu₃Cl₃

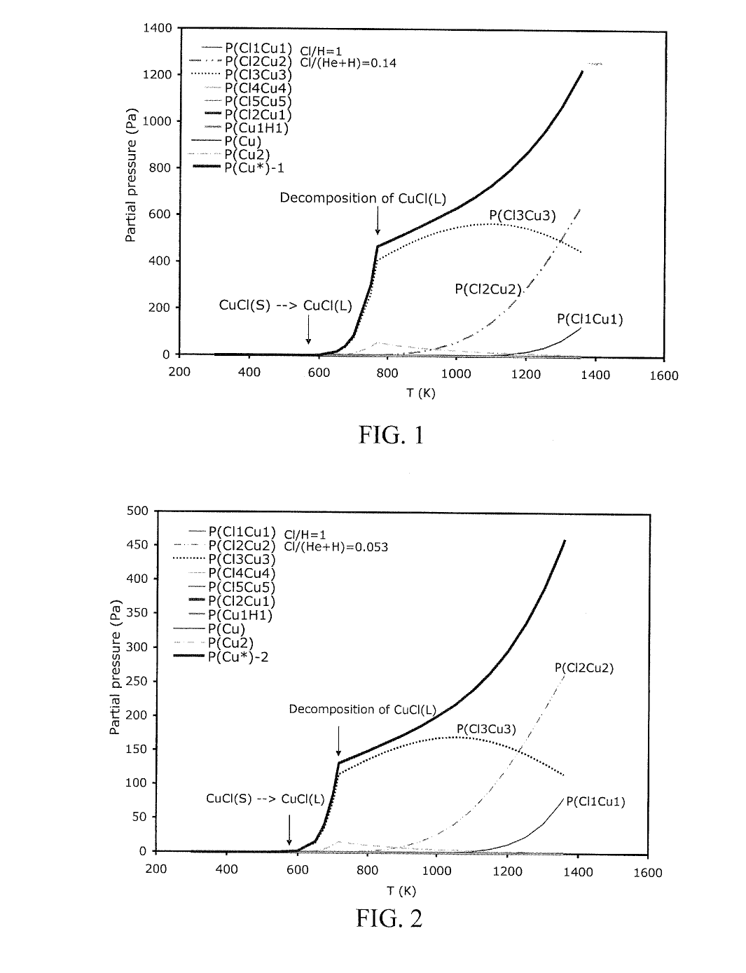

The equilibrium partial pressure of each vapor phase containing Cu at given thermodynamic conditions (Table 1) is presented in FIG. 1, where the P(Cu*) stands for the summation of vapor pressure of all available Cu-containing species. Apparently, the total partial pressure of Cu-containing species increases with temperature. The polymeric Cu₃Cl₃ is the main vapor species, as evidenced by highest partial pressure until around 1300K where the partial pressures of Cu₂Cl₂ and Cu₃Cl₃ cross over. The trimer Cu₃Cl₃ has been already reported as a main vapor species in many reports [Kle57, Gui71].

Klemperer et al. reported a cyclic polymer Cu₃Cl₃ as a principal species of cuprous chlorides based on the infrared spectrum of cuprous chloride vapor in equilibrium with the liquid [Kle57]. Guido et al. suggested that the trimer Cu₃Cl₃ is the mainly species with comparable values of partial pressure by the study of vapor phases in equilibrium with cuprous chloride using the Knudsen effusion-mass spectrometric technique [Gui71].

### 2.1.2 Inert Gas and Hydrogen Effect

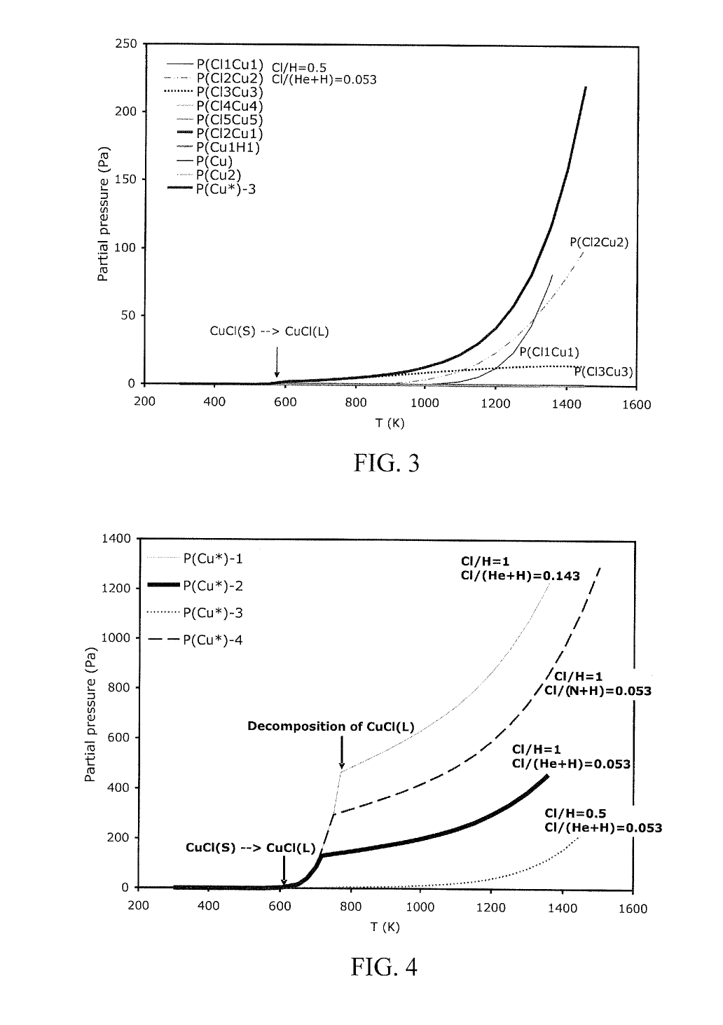

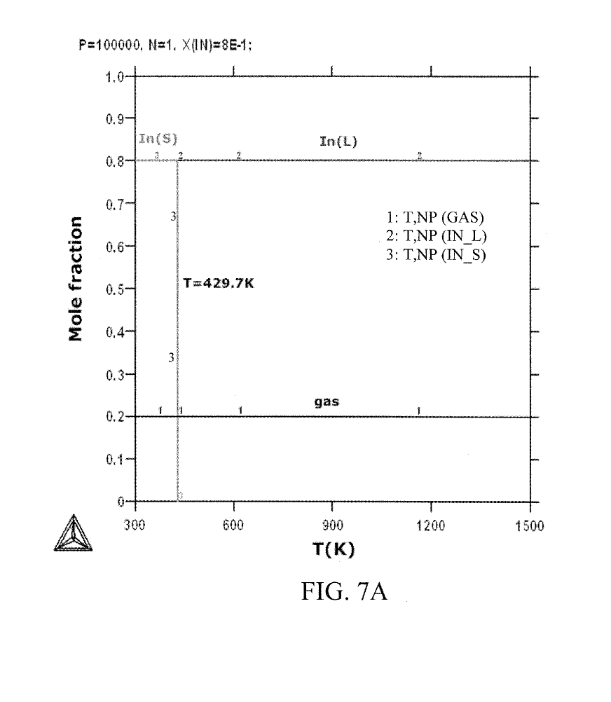

The equilibrium partial pressures of Cu-containing species at different inert conditions, [Cl]/([Inert]+[H])=0.143→0.053 are estimated in FIG. 2. The results demonstrate that the relative trend of partial pressures of Cu-containing vapor phases at lower [Cl]/([Inert]+[H]) ratio (run #2) is identical to those of run#1. However, it is evident that decreasing the absolute amount of Cl source by lowering [Cl]/([Inert]+[H]) ratio at the fixed [Cl]/[H] value leads to decrease of absolute values of total vapor pressures of Cu-containing species, which is graphically shown in FIG. 4.

The results of run #3 with lowest [Cl]/[H] (=0.5) and [Cl]/([Inert]+[H]) (=0.053) ratios, however, show the different temperature dependency of partial pressure. The comparison of the results for run#2 and run#3 shows that reducing the [Cl]/[H] ratio (e.g., 1.0→0.5) at the fixed [Cl]/([Inert]+[H]) (=0.053) ratio and constant [Cl] is likely to decrease the absolute value of partial pressure of Cu-containing species. It is mainly because excess hydrogen is likely to hinder chlorine from forming (CuCl)ₓ by producing HCl.

In run #4, nitrogen was adopted instead of helium as an inert gas. The results, which are not shown here, displayed the same pattern of temperature dependency as those for run #1 and #2. The total partial pressures of Cu-containing species for run #1 through #4 were compared in FIG. 4. In the equilibrium calculation, nitrogen consumes hydrogen to form NH₃ and consequently increase the effective [Cl]/([Inert]+[H]) and [Cl]/[H] ratios. Therefore, nitrogen is not an inert gas in the equilibrium system.

### 2.1.3 Halides (HCl, HBr, HI) Effect

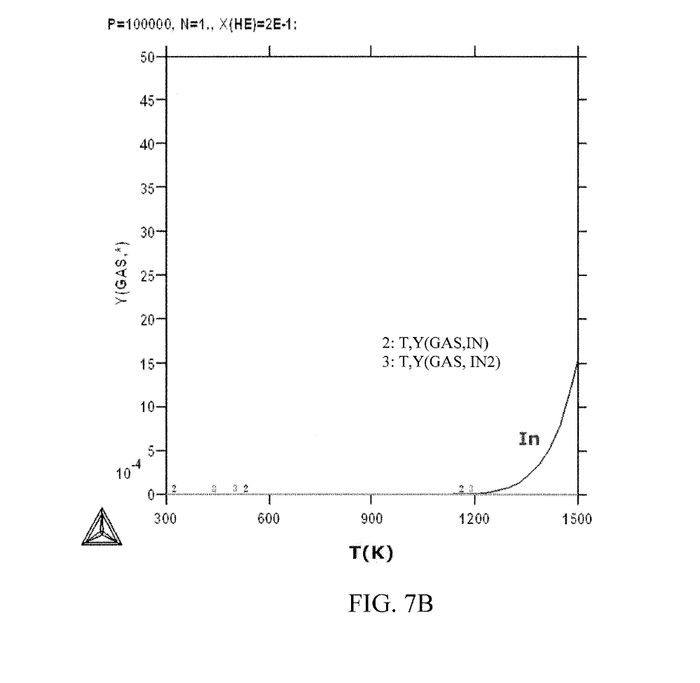

As described in the previous section, trimer Cu-halides including Cu₃Cl₃, Cu₃Br₃ and Cu₃I₃ are expected to be main vapor species in equilibrium. The Gibbs energies of formation for various Cu-halides formation reactions are summarized in Table 3 and FIG. 5.

TABLE 3
Gibbs energy of formation for various Cu-halides formation at 300 K

| | | ΔG_{reaction} (kJ/mol) |
|---|---|---|
| | Reaction of Cu-halides formation | at 300 K |
| 1 | 3Cu(s) + 3HCl(g) → Cu₃Cl₃(g) + 1.5 H₂(g) | 28.7 |
| 2 | 3Cu(s) + 3HBr(g) → Cu₃Br₃(g) + 1.5 H₂(g) | −28.3 |
| 3 | 3Cu(s) + 3HI(g) → Cu₃I₃(g) + 1.5 H₂(g) | −78.6 |
| 4 | 3Cu(s) + 1.5 Cl₂(g) → Cu₃Cl₃(g) | −257 |
| 5 | 3Cu(s) + 1.5 Br₂(g) → Cu₃Br₃(g) | −193 |
| 6 | 3Cu(s) + 1.5 I₂(g) → Cu₃I₃(g) | −103 |

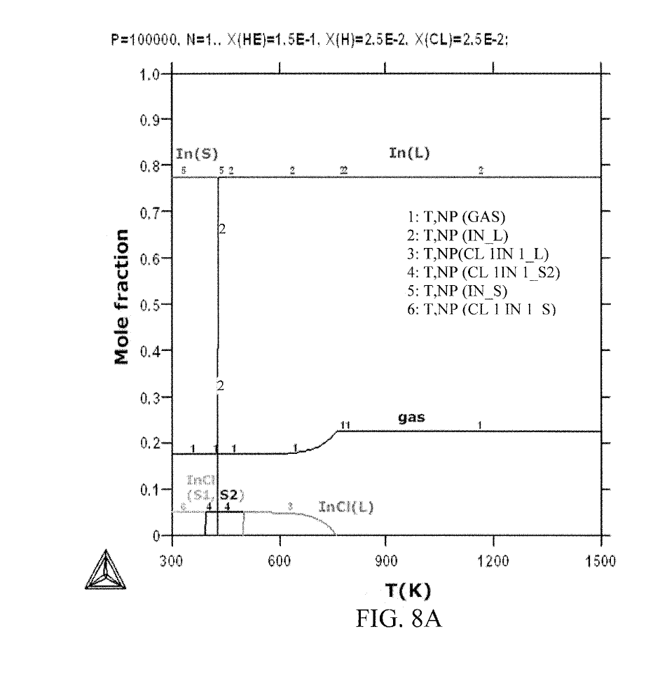

For different hydrogen halide carriers, e.g., HCl, HBr and HI with the input parameters given in Table 4, the equilibrium vapor pressures were calculated as shown in FIG. 6. Vapor species containing Cu considered in this calculation were summarized in Table 5. Interestingly, six vapor species of copper chlorides (Cu₁Cl₂, Cu₁Cl₁, Cu₂Cl₂, Cu₃Cl₃, Cu₄Cl₄, Cu₅Cl₅) are in equilibrium while only one copper bromide (Cu₃Br₃) and two copper iodides (Cu₁I₁, Cu₃I₃) are stable as vapor species.

TABLE 4
Input parameters for the equilibrium calculation of Cu source
with different hydrogen halide carriers.

| Carrier | | | | | | | |
|---|---|---|---|---|---|---|---|
| (HX) | N (mol) | x (N) | x (H) | x (X) | x (Cu) | X/H | X/(Inert + H) |
| HCl | 1 | 0.18 | 0.01 | 0.01 | 0.80 | 1.0 | 0.053 |
| HBr | 1 | 0.18 | 0.01 | 0.01 | 0.80 | 1.0 | 0.053 |
| HI | 1 | 0.18 | 0.01 | 0.01 | 0.80 | 1.0 | 0.053 |

Pressure: 1 × 10⁵ Pa, Temperature: 300~1500 K
Inert gas: N_{2KL}
Transport gas: HX (X = Cl, Br, I)

TABLE 5
Vapor species containing Cu considered in equilibrium calculation
with different hydrogen halide carriers.

| Carrier gas | Vapor species containing Cu |
|---|---|
| HCl | Cu, Cu₂, Cu₁H₁, Cu₁Cl₂, Cu₁Cl₁, Cu₂Cl₂, Cu₃Cl₃, |
| | Cu₄Cl₄, Cu₅Cl₅ |
| HBr | Cu, Cu₂, Cu₁H₁, Cu₃Br₃ |
| HI | Cu, Cu₂, Cu₁H₁, Cu₁I_{1,} Cu₃I₃ |

From the comparison of the total vapor pressures of Cu-containing vapor species for different hydrogen halide carriers shown in FIG. 6, the selection of the appropriate halide carrier is likely to depend on the operation temperature. Based on the results using the current input parameters, hydrogen chloride (HCl) will be better than the others (HBr and HI) for the temperature range from 600 to 950K while hydrogen iodide (HI) may be preferred for the temperature range from 950 to 1450K. The preferred temperature range would be changed by the operation conditions including pressure, inert gas (N₂ or He) and equilibrium gas compositions. For example, considering the conventional growth temperature (500˜600° C.) of CIS and CGS, hydrogen chloride will be preferred as a carrier gas of CIGS CVD process.

### 2.2 Indium Source

Thermodynamic equilibrium calculation for indium source with a HCl carrier gas and He inert gas was performed using the self-consistent database obtained from ThermoCalc SUB94 database by ThermoCalc software. The input parameters and In-containing vapor species considered in this equilibrium calculation are summarized in Tables 6 and 7, respectively. To understand the effects of hydrogen (H₂) and hydrogen choloride (HCl) on the phase equilibrium of In—H—Cl—He system, different Cl/H and Cl/(He+H) ratios are used.

TABLE 6
Input parameters for the equilibrium calculation of indium source.

| Run# | N (mol) | x (He) | x (H) | x (Cl) | x (In) | Cl/H | Cl/(He + H) |
|---|---|---|---|---|---|---|---|
| In-1 | 1 | 0.20 | 0 | 0 | 0.80 | 0 | 0 |
| In-2 | 1 | 0.15 | 0.025 | 0.025 | 0.80 | 1.0 | 0.143 |
| In-3 | 1 | 0.18 | 0.01 | 0.01 | 0.80 | 1.0 | 0.053 |
| In-4 | 1 | 0.17 | 0.02 | 0.01 | 0.80 | 0.5 | 0.053 |
| In-5 | 1 | 0 | 0.01 | 0.01 | 0.98 | 1.0 | 1.0 |

Pressure: 1 × 10⁵ Pa, Temperature: 300~1500 K
He: Inert gas
HCl: Transport gas

TABLE 7
Vapor species containing indium considered in
equilibrium calculation with a carrier gas of HCl.

In, In₂
In₁H₁
In₁Cl₁, In₂Cl₂, In₁Cl₂, In₂Cl₄, In₁Cl₃, In₂Cl₆,

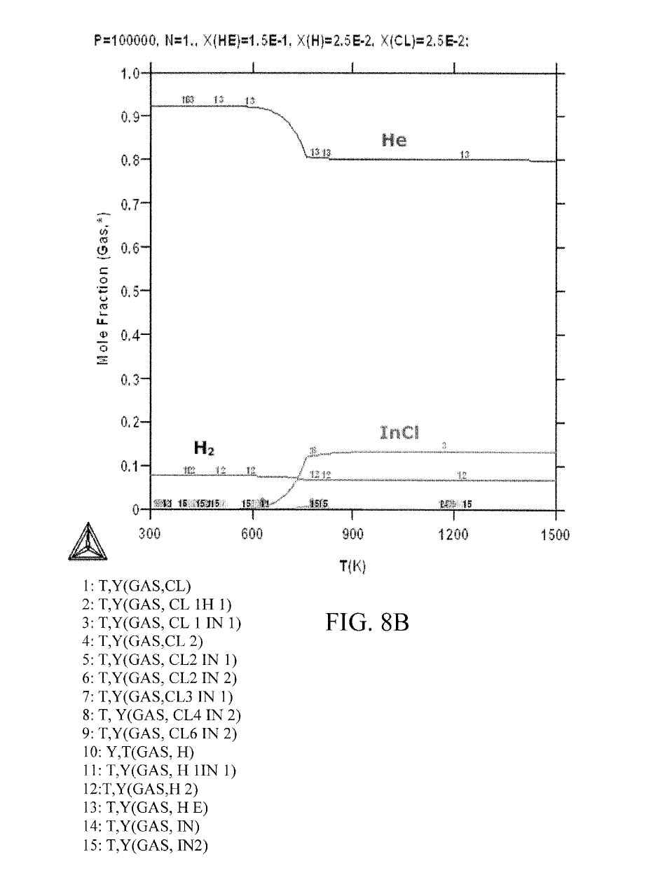

The calculation results of run #(In-1) with only In and He are shown in FIG. 7. The results show that the melting temperature of indium is around 429.7K and liquid indium is very stable within the given temperature range (˜1500K). Gas phase is mainly composed of helium, and gas phase indium starts to appear above 1200K. Therefore, an additional transport gas (e.g., HCl) is required to produce sufficient vapor pressure of In-containing species.

In run #(In-2) through (In-5), hydrogen chloride (HCl) is introduced as a transport gas. For the calculation of run #(In-2), (In-3) and (In-5), hydrogen and chlorine are assumed to be only provided in a form of HCl and thus [Cl]/[H] ratio is equal to 1 while the [Cl]/[H]<1 composition is applied for the run #(In-4) by adopting an extra carrier gas of H₂.

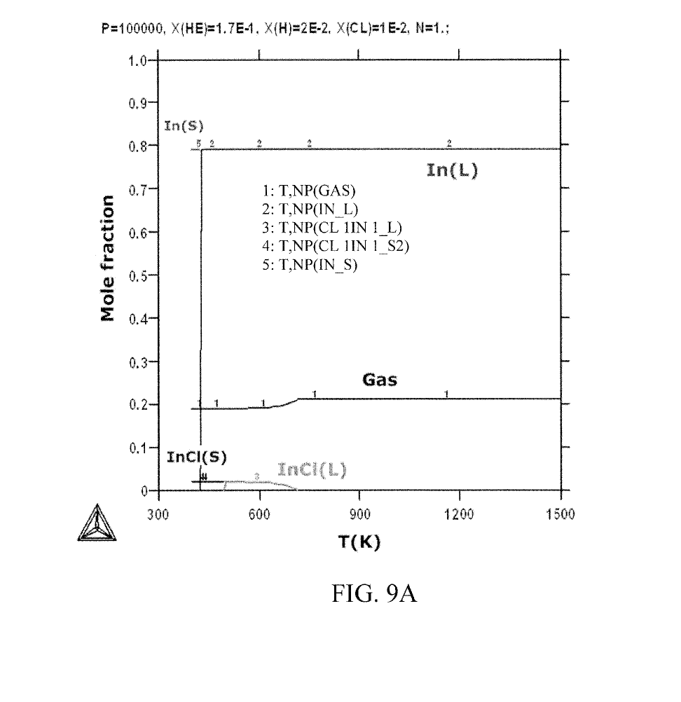

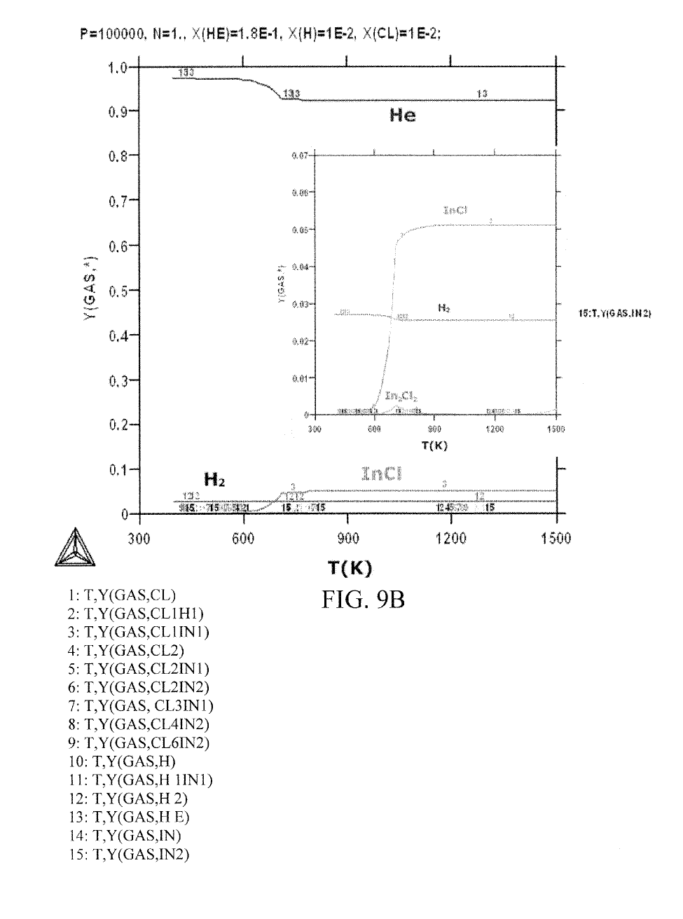

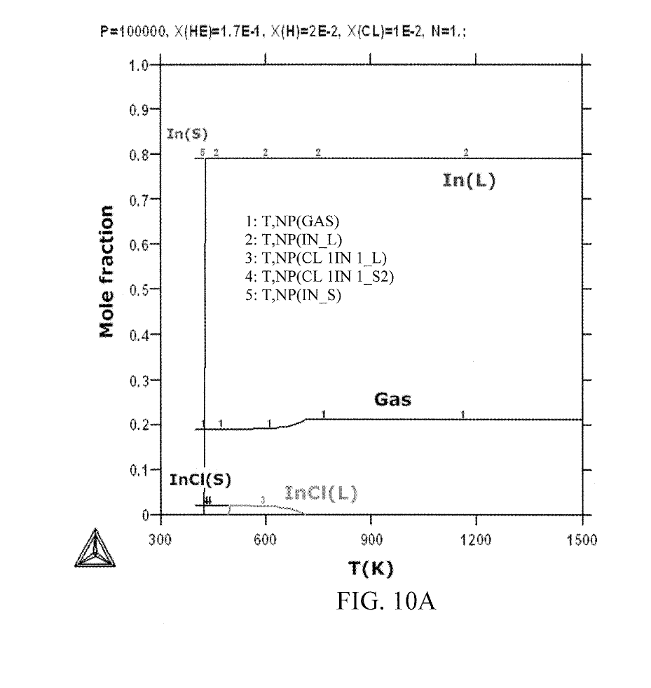

As shown in FIG. 8(a)-10(a), the results show that the pure indium (solid/liquid) and indium monochloride, InCl (solid/liquid) are expected as stable condensed phases. The composition profile of gas phases shown in FIG. 8(b)˜10(b) reveals that indium monochloride (InCl) is an expected major In-containing gas phase which would participate in the formation reaction of CuInSe₂ in deposition zone of CVD reactor. It should be noted that a relatively small amount of dimeric indium chloride (In₂Cl₂) also is calculated at the temperature range of 600 to 800K.

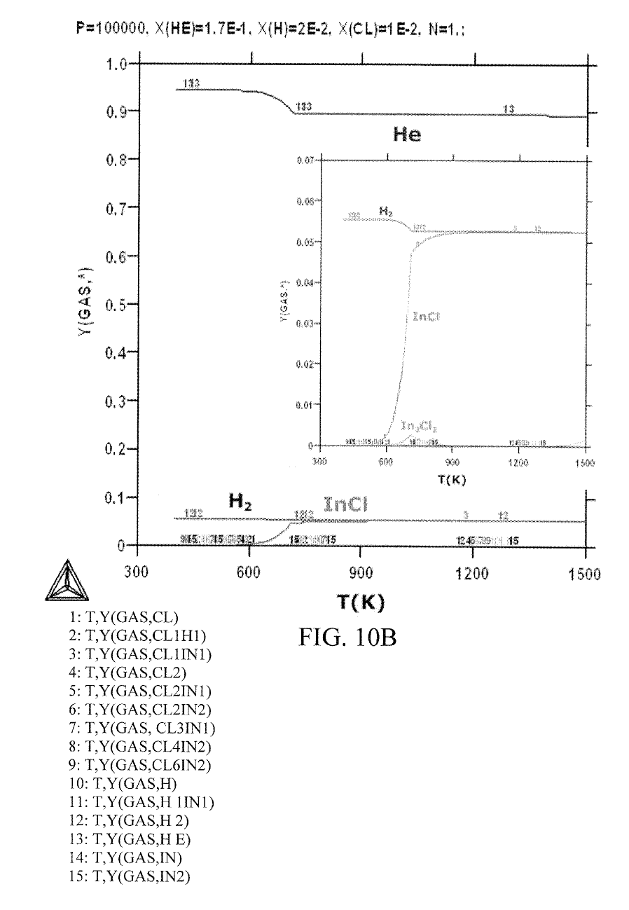

For the different [Cl]/[H] and [Cl]/([He]+[H]) ratios, the equilibrium partial pressures of major In-containing gas phase, InCl, are compared in the FIG. 11. The results demonstrate that the absolute amount of chlorine in gas phase, [Cl]/([He]+[H]), is more important than [Cl]/[H] ratio. Furthermore, the operational temperature range for CVD process can be extracted from the plateau regions in FIG. 11. The minimum temperature to establish the plateau vapor pressure region varies between 600 and 860K depending on the composition, mainly [Cl]/([He]+[H]) ratio. The higher [Cl]/([He]+[H]) ratio should guarantee the higher vapor pressure of InCl, but also requires the higher source temperature to get a stable InCl flux.

### 2.3 Selenium Source

Thermodynamic equilibrium calculation for selenium was performed using ThermoCalc software with the self-consistent SUB94 database. Since selenium is relatively very volatile, only the inert helium is adopted as a carrier gas.

TABLE 8
Input parameters for the equilibrium calculation of selenium source.

| Run # | Pressure (Pa) | Temperature (K) | N (mol) | x (He) | x (Se) |
|---|---|---|---|---|---|
| Se-1 | 1 × 10⁵ | 300~1500 | 1 | 0.20 | 0.80 |
| Se-2 | 1 × 10⁵ | 300~1500 | 1 | 0.01 | 0.99 |

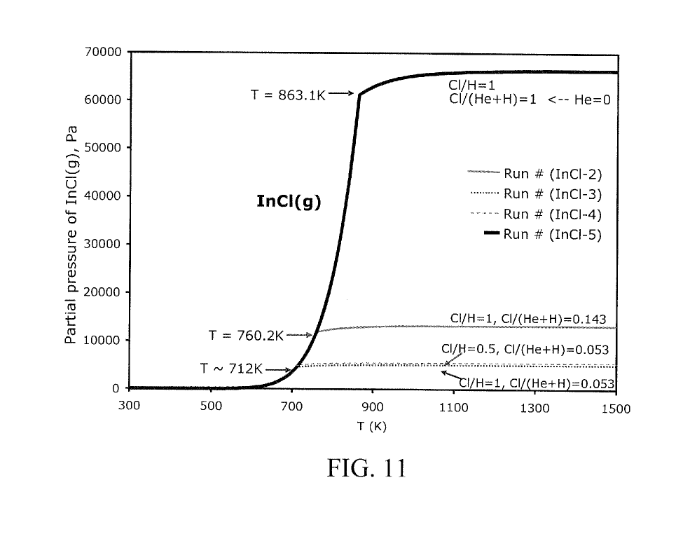

The calculation results for two different compositions are shown in FIG. 12. Solid and liquid selenium are only condensed phases with a melting temperature of 494K (˜221° C.). However, the temperature where the liquid selenium completely disappears is likely to depend on the composition of He/Se. The higher Se concentration requires the higher temperature for complete disappearance of liquid Se, e.g., 939K for x(He)=0.2 and 990K for x(He)=0.01. Also, it should be noted that the liquid Se disappears more abruptly at higher Se concentration.

To utilize the pure selenium as a selenium source for CVD with a He carrier gas, the source temperature should be carefully determined so that the flux of Se can be not only sufficient for CIS formation, but also precisely controllable. Based on the FIG. 12, temperature range of around 800˜900K at atmospheric pressure may be suggested.

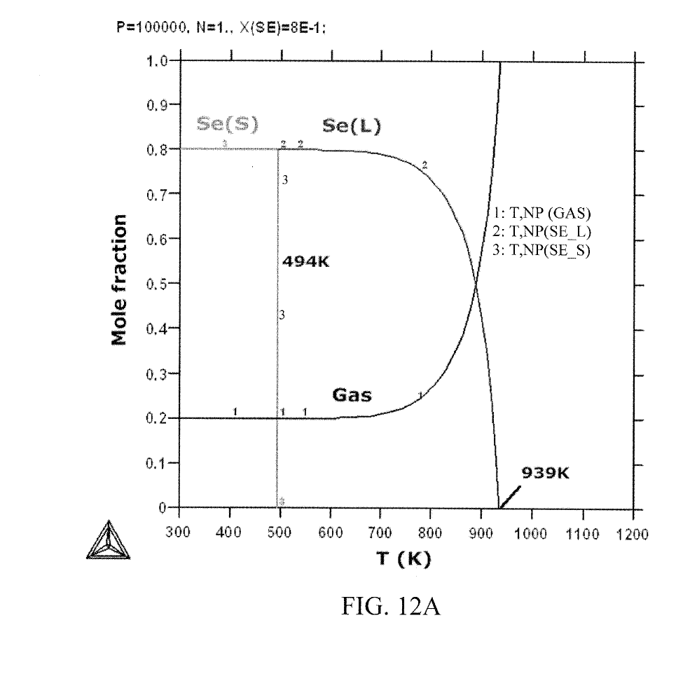

The gas phase of selenium is known to have the various forms of compounds, i.e., Se₁ through Se₈ [Cha99] as shown in FIG. 13. The Se₂, Se₅ and Se₆ are the major species in equilibrium with liquid selenium for 494K<T<˜900K, and only Se2 is dominant at higher temperature (T>900K). The concentration profile of gas phase for run #(In-2), which is not shown here, follows exactly the same pattern as that for run #(In-1).

### Thermodynamic Equilibrium Calculation for CuInSe₂ Compound

### 3.1 CVD Process for CuInSe₂ Formation

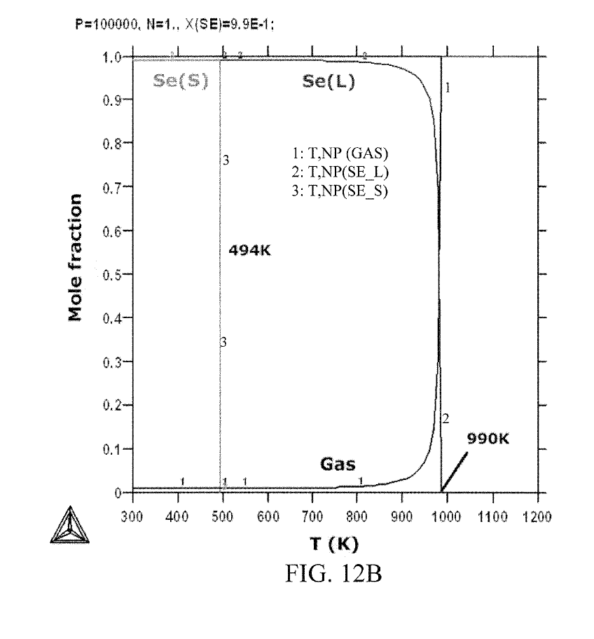

Based on the equilibrium calculation for the source materials with carrier gases, a schematic CuInSe₂ CVD process is suggested as shown in FIG. 14. For the traditional CVD reactor, three different zones such as source, mixing and deposition zone are required. Each source needs its own carrier gas and heating element with a separate temperature controller since all three source temperatures should be controlled separately during the deposition. As confirmed in the previous section, Cu₃Cl₃, InCl and Se₂ are expected to be a major vapor species for Cu, In and Se, respectively.

### 3.2 Thermochemical Equilibrium Calculation for CuInSe₂ Formation

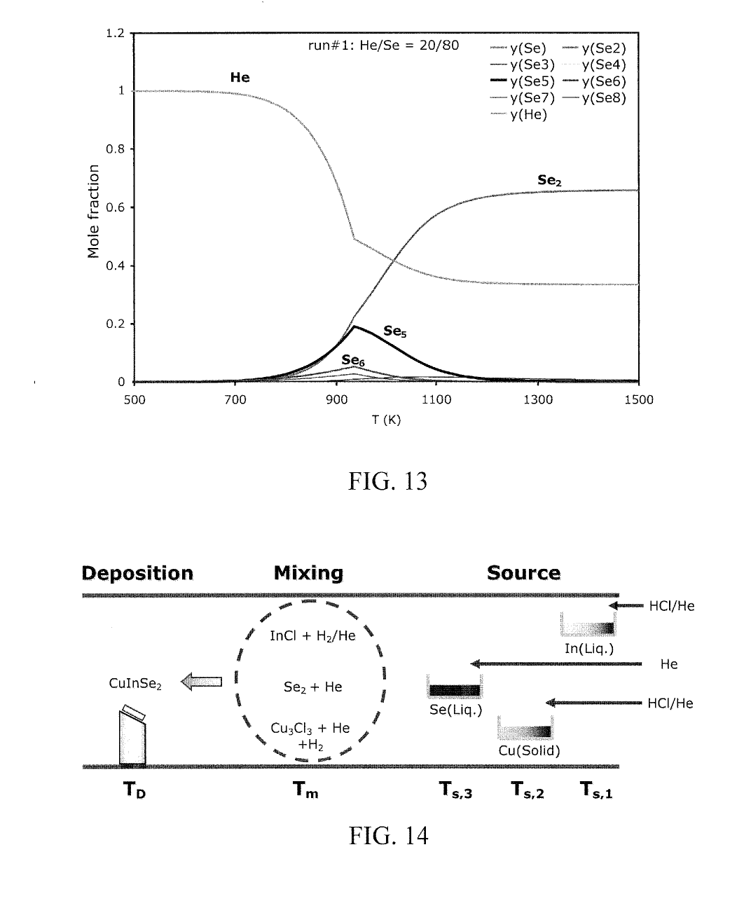

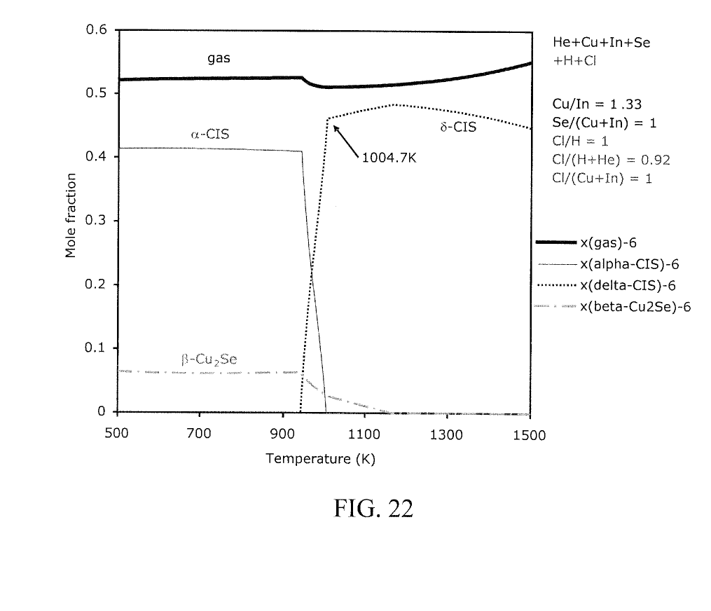

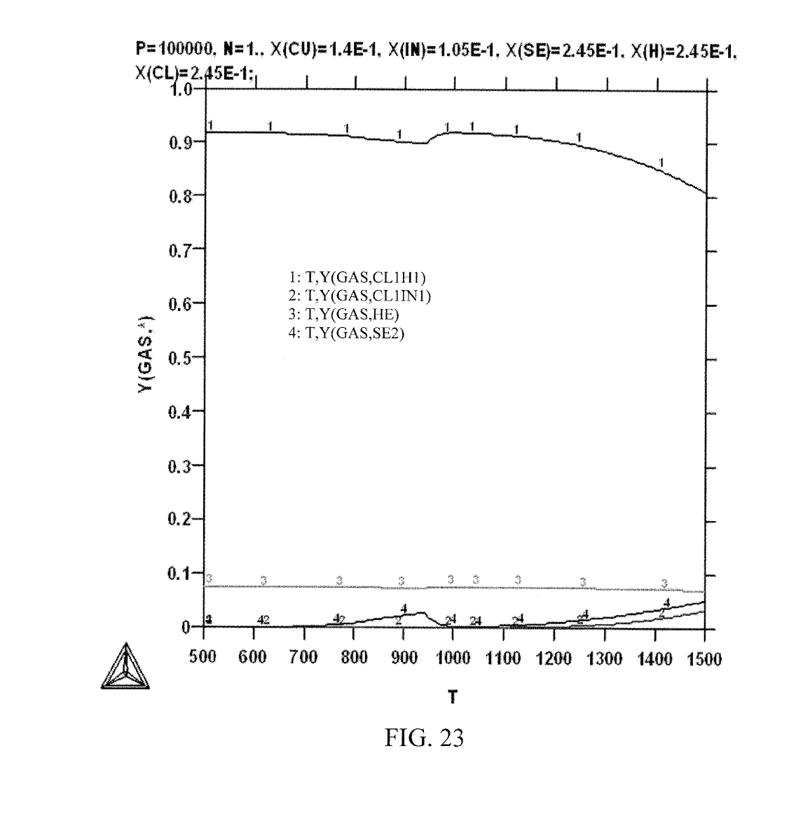

Thermochemical equilibrium calculation for CuInSe₂ CVD process was performed using ThermoCalc program with a built-in SUB94 database and our own CuInSe₂ database [She06]. Six different sets of input parameters and their calculation results are summarized in Table 9 and FIG. 15 through 23, respectively. For all cases, atmospheric pressure (˜1×10⁵ Pa) is assumed, and HCl and He are used as a transport and inert gas, respectively. For run #CIS-1 through #CIS-4, the thermodynamic equilibrium of Cu—In—Se compounds having different compositions without hydrogen chloride (HCl) was calculated, while HCl was introduced in run #CIS-5 and 6.

TABLE 9
Input parameters for the equilibrium calculation of CuInSe₂ formation.

| Run | x (Cu) | x (In) | x (Se) | x (He) | x (H) | x (Cl) | Cl/H | Cl/(He + H) | Cu/In | Se/(Cu + In) |
|---|---|---|---|---|---|---|---|---|---|---|
| CIS-1 | 0.245 | 0.245 | 0.49 | 0.02 | 0 | 0 | 0 | 0 | 1 | 1 |
| CIS-2 | 0.28 | 0.21 | 0.49 | 0.02 | 0 | 0 | 0 | 0 | 1.33 | 1 |
| CIS-3 | 0.21 | 0.28 | 0.49 | 0.02 | 0 | 0 | 0 | 0 | 0.75 | 1 |
| CIS-4 | 0.2 | 0.2 | 0.58 | 0.02 | 0 | 0 | 0 | 0 | 1.00 | 1.45 |
| CIS-5 | 0.1225 | 0.1225 | 0.245 | 0.02 | 0.245 | 0.245 | 1 | 0.92 | 1 | 1 |
| CIS-6 | 0.14 | 0.105 | 0.245 | 0.02 | 0.245 | 0.245 | 1 | 0.92 | 1.33 | 1 |

Pressure: 1 × 10⁵ Pa, Temperature: 300~1500K
Inert gas: He
Transport gas: HCl

In run #CIS-1, the stoichimetric composition of Cu—In—Se, i.e., [Cu]/[In]=1.00 and [Se]/[Cu+In]=1.00, was assumed. As shown in FIG. 15, only pure CuInSe₂ is stable and no other secondary phases are expected to be stable. The abrupt phase transformation of α-CuInSe₂ into high-temperature stable phase, δ-CuInSe₂, is expected at the temperature of ˜1043.4K.

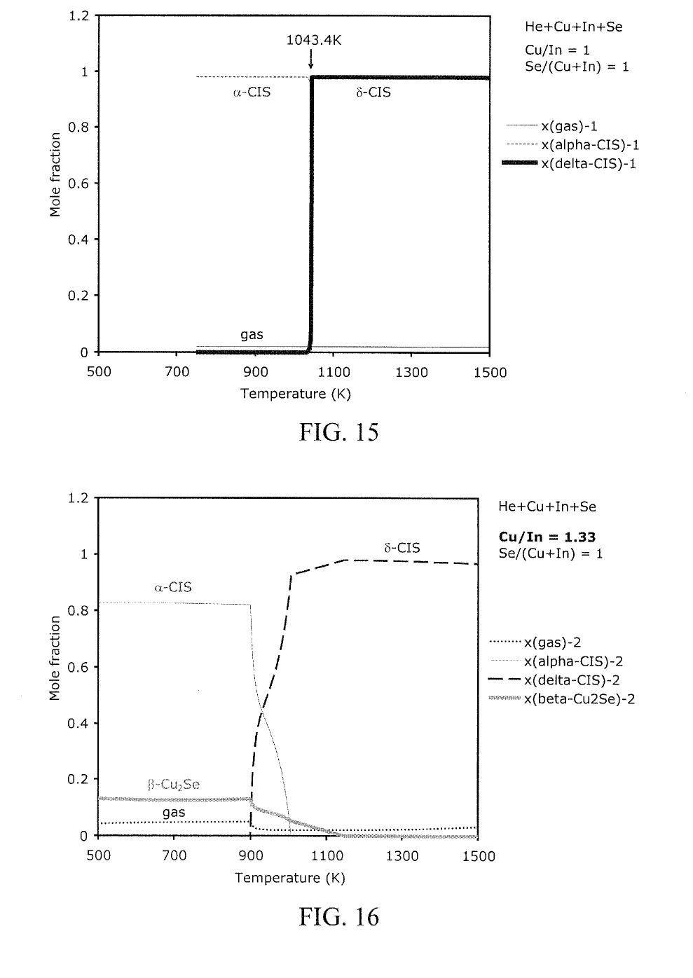

The outputs of run #CIS-2 with the Cu-rich composition of Cu—In—Se, i.e., [Cu]/[In]=1.33 and [Se]/[Cu+In]=1.00, are shown in FIG. 16. In addition to the stable α-CuInSe₂, the secondary β-Cu₂Se was found to be stable in a low temperature region (<900K). The phase transition from α-CuInSe₂ to δ-CuInSe₂ is expected at the temperature between 899.3 and 1005.8K, which is lower than the transition temperature (˜1043.4K) for the stoichiometric conditions (#CIS-1)

The calculation results for run #CIS-3 with the In-rich composition of Cu—In—Se, i.e., [Cu]/[In]=0.75 and [Se]/[Cu+In]=1.00, are shown in FIG. 17. For a low temperature region (<770K), the InSe as well as α-CuInSe₂ are thermally stable. The α-CuInSe₂ phase begins to transform into δ-CuInSe₂ at around 771.0K, which is much lower than the values expected for the stoichiometric (˜1043.4K) and Cu-rich (˜899.3K) conditions. Also, it should be noted that the co-existing region of α-CuInSe₂ and δ-CuInSe₂ (T=771.0˜1000.0K) is much wider than those for the stoichiometric (1042.0˜1043.4K) and Cu-rich (899.3˜1005.8K) conditions. The low temperature stable InSe phase will release selenium to form In₄Se₃ between 771.0 and 773.6K as shown in the inset of FIG. 17.

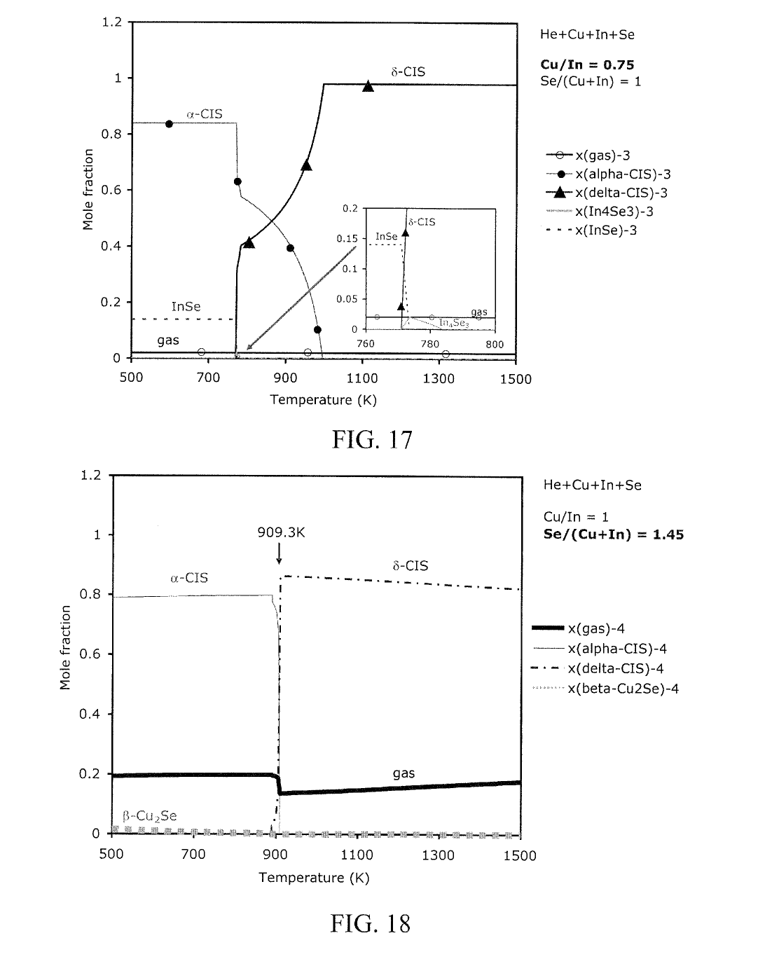

The calculation results for run #CIS-4 with the Se-rich composition of Cu—In—Se, i.e., [Cu]/[In]=1.00 and [Se]/[Cu+In]=1.45, are displayed in FIG. 18. The steep transformation of α-CuInSe₂ into δ-CuInSe₂ would happen at the temperature around 909.3K. A very small amount of β-Cu₂Se (<2%) is expected at low temperature region (<909K). It is interesting to note that the mole fraction of gas phase reaches almost x(gas)˜0.2 which is relatively higher than those in the other cases, e.g., x(gas)<0.05 for run #CIS-1˜3.

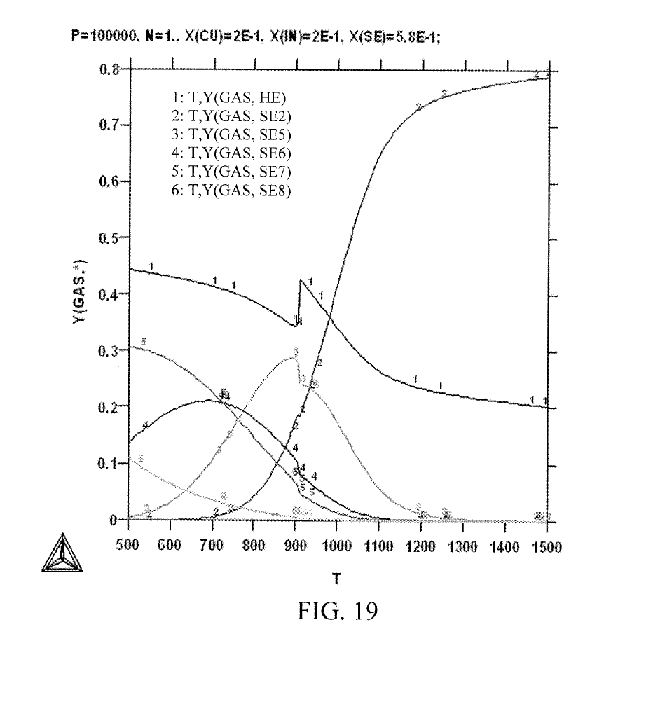

Higher mole fraction of gas phases results mainly from the excess selenium with a high vapor pressure. As shown in FIG. 19, the vapor phase composes of helium and several selenium vapors (e.g., Se₂, Se₅, Se₆, Se₇, Se₈).

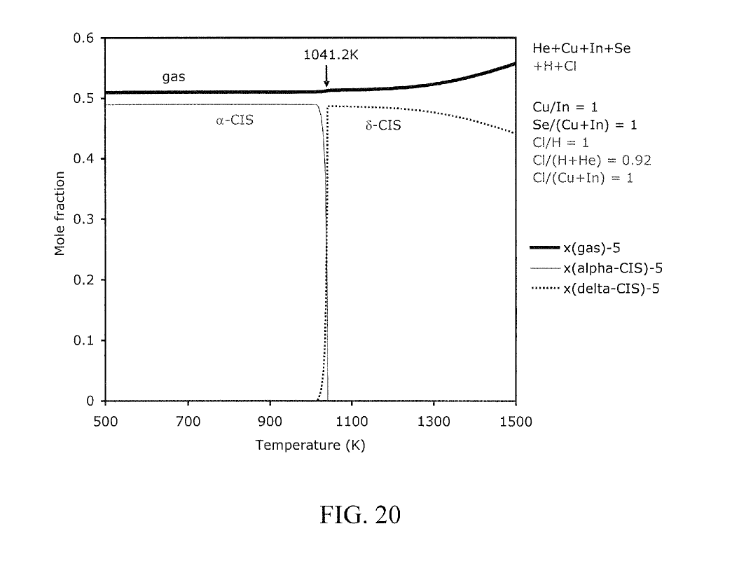

Next, a carrier gas, HCl, is included in the calculation of run #CIS-5 with the stoichiometric composition of Cu—In—Se, i.e., [Cu]/[In]=1.00 and [Se]/[Cu+In]=1.00. With the assumption of no input of extra hydrogen and chlorine gas, the [Cl]/[H] ratio is set to be identical. The calculation results shown in FIG. 20 are very similar to that for run #CIS-1 (FIG. 15) with the stoichiometric Cu—In—Se without HCl. For the both conditions of run #CTS-1 and CIS-5, no condensed phases of byproducts are expected and the phase transformation of α-CuInSe₂ into δ-CuInSe₂ occurs abruptly in the temperature range of around 1041˜1043K. One main difference between run #CIS-1 and CIS-5 is the earlier decomposition of δ-CuInSe₂ in run #CIS-5, which is attributed to the reactivity of HCl.

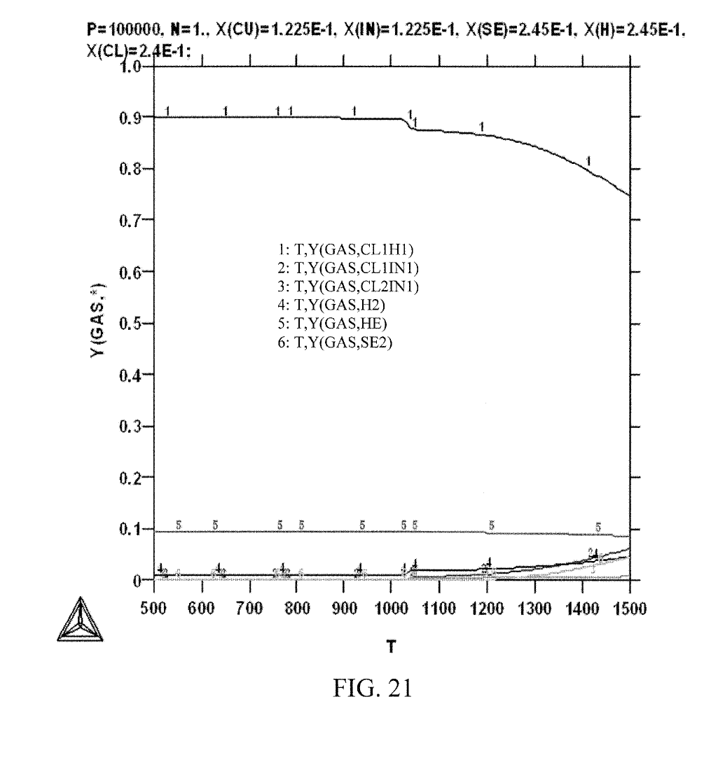

As demonstrated in the composition profile of vapor phases in FIG. 21, the decomposition of δ-CuInSe₂ by the attack of HCl gas leads to the formation of InCl gas with accompanying the generation of H₂ and Se₂ gas at the temperature above around 1100K. Hence, the decomposition reaction can be expressed as:

δ-CuInSe₂+HCl(g)→InCl(g)+Cu+Se₂(g)+½H₂(g).

In the calculation of run #CIS-6 with the Cu-rich composition of Cu—In—Se, i.e., [Cu]/[In]=1.3, [Se]/[Cu+In]=1.00, the HCl is introduced as a transport gas. Overall phase profile is very similar to the results of run #CIS-2 having the same composition except no HCl. Besides the stoichiometric α-CuInSe₂, the secondary phase β-Cu₂Se was identified as an additional stable phase at the temperature below 942K. The phase transformation from α-CuInSe₂ to δ-CuInSe₂ is expected to occur at the temperature range of 942˜1005K, and followed by the decomposition of δ-CuInSe₂ starting at around 1167K.

The vapor phase is mainly composed of HCl transport gas. As temperature increases, Se₂ vapor which is a major gas phase species of Se appears and then is consumed to form δ-CuInSe₂. Once δ-CuInSe₂ is decomposed, the gas phase Se₂ and InCl are produced by the following reaction:

δ-CuInSe₂+HCl(g)→InCl(g)+Cu+Se₂(g)+½H₂(g).

### 4. Continuous 3-Stage CVD Process for CuInSe₂ Formation

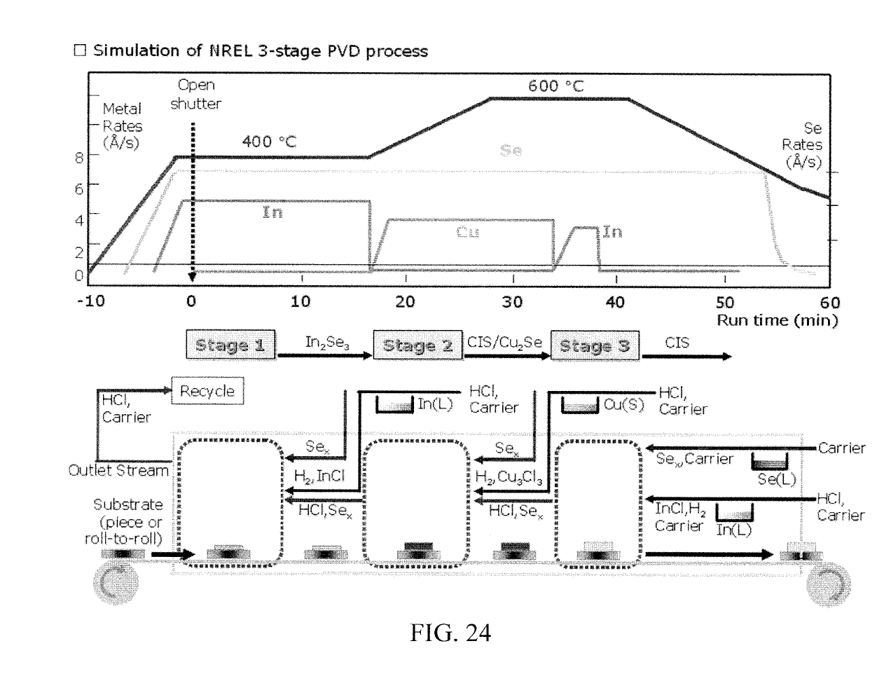

In previous section, the feasibility of chemical vapor deposition (CVD) for CuInSe₂ formation was demonstrated. A continuous CVD process to simulate a traditional 3-stage physical vapor deposition scheme which is known to produce the best CIGS solar cell efficiency (˜19.5%) is suggested in FIG. 24.

At the first stage of NREL 3-stage PVD process, the In and Se are deposited to form the sesquiselenide, In₂Se₃ at a relatively low temperature 400° C. After the second stage having only Cu and Se flux, a Cu-rich CIS is produced along with a secondary Cu—Se binary compound, mainly conducting Cu₂Se, which is known to facilitate the CIS grain growth. Finally, a slightly Cu-poor CIS forms by adding more In at third stage.

The continuous CVD process features a moving substrate (or roll-to-roll) and a counter flow of gas reactants transported by carrier gases to minimize the waste of reactant materials as shown in FIG. 24. To realize the NREL 3-stage process having a different gas composition at each stage, two supplementary gas inlets (i.e., InCl/H₂ and Cu₃Cl₃/H₂) are added. Outlet stream, which is mainly composed of carrier gases (e.g., HCl and He) and a minor amount of unreacted materials (i.e., Cu, In and Se), goes to the recycle unit to recover reusable materials separately.

This continuous reactor design eliminates downtime associated with substrate loading, reactor startup, and shutdown which are required for a typical batch reactor system. Furthermore, substrate traveling at constant velocity under steady state reactor conditions will produce highly uniform films.

Deposition rate depends on the reaction zone residence time, reactant gas flow rates, substrate temperature, as well as other operating variables and design parameters. Substrate moving speed is directly related to residence time in the reaction region. Lower speed of substrate results in higher residence time and thus increases the deposition rate.

It should be understood that the examples and embodiments described herein are for illustrative purposes only and that various modifications or changes in light thereof will be suggested to persons skilled in the art and are to be included within the spirit and purview of this application and the scope of the appended claims. In addition, any elements or limitations of any invention or embodiment thereof disclosed herein can be combined with any and/or all other elements or limitations (individually or in any combination) or any other invention or embodiment thereof disclosed herein, and all such combinations are contemplated with the scope of the invention without limitation thereto.

### REFERENCES

[Kle57] W. Klemperer, S. A. Rice, R. S. Berry, J. Am. Chem. Soc. 79 (1957) 1810.
[Gui71] M. Guido, G. Balducci, G. Gigli and M. Spoilt, J. Chem. Phys. 55 (1971) 4566.
[She06] J. Shen, W. K. Kim, S. Shang, M. Chu, S. Cao and T. J. Anderson, Rare Metals 25(5) (2006) 481.
[Cha99] C.-H. Chang, Ph.D. Dissertation, U. of Florida (1999).
D. Fischer, T. Dylla, N. Meyer, M. E. Beck, A. Jäger-Waldau and M. Ch. Lux-Steiner, Thin Solid Films 387 (2001) 63-66.
[Kun05] S. Kunjachan, I. Korah and M. A. Ittyachen, Cryst. Res. Technol. 40(9) (2005) 871-876.

1-28. (canceled)

29. A method for forming a Cu(InₓGa₁₋ₓ)(Se_{y}S_{1-y})₂ film, comprising:
a) introducing a Group VI source to a reactor;
b) introducing a Group III source to a reactor;
c) introducing a copper source to a reactor;
d) introducing the Group VI source, the Group III source, and the copper source in a reactor; and
e) forming a Cu(InₓGa₁₋ₓ)(Se_{y}S_{1-y})₂ film on a substrate in a reactor,
wherein x=0 to 1 or fractional values between 0 and 1 and y=0 to 1 or fractional values between 0 and 1 and said reactor is a single reactor or multiple reactors.

30. The method of claim 29, wherein said substrate is moved continuously through the reactor(s) or is stationary within the reactor(s).

31. The method of claim 29, wherein said substrate is a moving substrate that moves through the reactor(s).

32. The method of claim 29, wherein said substrate is a roll-to-roll substrate.

33. The method of claim 29, wherein said substrate is a silicon wafer, plastic, resin, glass, ceramic, or metal object or film, GaAs layer or any semiconductor layer or device.

34. The method of claim 33, wherein said substrate is a soda lime glass.

35. The method of claim 33, wherein said substrate is a silicon oxide-based glass.

36. The method of claim 29, wherein the Group VI source is pure selenium or contains selenium, contains sulfur or is pure sulfur or is any mixture thereof.

37. The method of claim 29, wherein the Group III source contains In, trimethyl indium or other organo-indium compound, indium trichloride, indium monochloride or combinations thereof.

38. The method of claim 29, wherein the Group III source contains Ga, trimethyl gallium or other organo-gallium compound, gallium trichloride or combinations thereof.

39. The method of claim 29, wherein the copper source contains Cu.

40. The method of claim 29, wherein the sources of selenium, sulfur, indium, gallium, and/or copper are independently introduced into the reactor(s) in a carrier gas.

41. The method of claim 40, wherein the carrier gas is helium or other carrier gas.

42. The method of claim 40, wherein the carrier gas also contains HCl.

43. The method of claim 40, wherein the carrier gas with the copper source comprises helium or other carrier gas and HCl.

44. The method of claim 40, wherein the carrier gas with the copper source comprises nitrogen and HCl.

45. The method of claim 29, further comprising recovering unreacted materials in a recycling unit.

46. The method of claim 45, further comprising separating the unreacted materials.

47. The method of claim 29, wherein the temperature of the reactor(s) is in the range of about 300K to about 1500K.

48. The method of claim 47, wherein the temperature of the reactor(s) is in the range of about 573K to about 973K.

49. The method of claim 29, wherein the pressure of the reactor(s) is in the range of about 1×10⁰ to 1×10⁵ Pa.

50. The method of claim 29, further comprising the deposition of additional materials on said substrate.

51. The method of claim 40, wherein said sources are reacted with HCl, HI, HBr or combinations thereof within said carrier gas.

52. A CuInₓGa₁₋ₓ(Se_{y}S_{1-y})₂ coated substrate produced according to the method of claim 29.

53. The CuInₓGa₁₋ₓ(Se_{y}S_{1-y})₂ coated substrate of claim 52, wherein said substrate is a silicon wafer, plastic, resin, glass, ceramic, or metal object or film, GaAs layer or any semiconductor layer or device.

54. A device or solar cell comprising a chemical vapor deposited CuInₓGa₁₋ₓ(Se_{y}S_{1-y})₂ on a substrate produced according to the method of claim 29.

55. The device of claim 54, wherein said device is an electronic device.

56. The device of claim 54, wherein said device is a photovoltaic device.
